(19) United States
(12) Patent Application Publication
(10) Pub. No.: US 2005/0239250 A1
(43) Pub. Date: Oct. 27, 2005

(54) Ultra dense non-volatile memory array

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/168,834

(22) Filed: Jun. 28, 2005

Related U.S. Application Data
(63) Continuation-in-part of application No. 10/639,073, filed on Aug. 11, 2003, now Pat. No. 6,933,557.

(51) Int. Cl. H01L 21/336

(52) U.S. Cl. 438/258

(57) ABSTRACT

Twin side-by-side non-volatile memory transistors have a common T-shaped control gate over mirror image floating gates sharing a common subsurface electrode between the floating gates. Select transistors on either side of the transistor pair, in combination with the common control gate allow selection of individual transistors in an array of rows and columns, without isolation between devices in the array. The device is made with three layers of polysilicon or poly. A first poly layer is used to form floating gates. A second poly layer is used for the T-shaped control gates. A third poly layer is used as a gate for select transistors between memory transistor pairs.

### CROSS-REFERENCE TO RELATED APPLICATION

This application is a continuation-in-part of prior application Ser. No. 10/639,073; filed Aug. 11, 2003; now U.S. Pat. No. ______.

### TECHNICAL FIELD

The invention relates to non-volatile memory arrays and, in particular, to an architecture for non-volatile memory devices in a compact arrangement, and a method of making same.

### BACKGROUND ART

Most MOS integrated circuit transistors on the same chip and with subsurface channels are constructed within isolation areas so that isolated devices can independently interact with each other or a remote system. In MOS device fabrication, isolation structures prevent formation of parasitic channels between devices, thereby preventing unwanted current paths and device cross-talk. For example, the well-known LOCOS technique, LOCOS being an acronym for “local oxidation of silicon”, features formation of a peripheral oxide barrier to define an active area where a transistor or other device is built. The oxide barrier extends completely around the device and also extends into the substrate to a depth usually greater than, or comparable to, the source or drain depth. The chip area consumed by isolation structures is often larger than the area used by devices because the isolation structures are at the periphery of each device and the amount of area for a peripheral boundary structure can easily exceed the area within the boundary. Other isolation technologies may consume less space, but all such technologies consume some space and may be difficult to implement or have other drawbacks. As device sizes become smaller and smaller, the amount of space dedicate to isolation structures becomes quite significant.

Twin EEPROM transistors are shown in the prior art as structures that save space by sharing of circuit elements. For example, see U.S. Pat. No. 6,160,287 to Chang; U.S. Pat. No. 6,486,032 to Lin; and U.S. Pat. No. 6,468,863 to Hsieh et al.

An object of the invention was to devise a dense non-volatile memory array where isolation structures are not needed.

### SUMMARY

The above object has been achieved with a non-volatile memory device and array architecture that avoids isolation structures with a tight architecture using a shared subsurface source or drain electrode symmetrically located between twin non-volatile memory transistors fabricated on a lightly doped semiconductor substrate. No isolation between memory transistors is needed because only one memory transistor is activated at a time. The twin side-by-side memory transistors allow increased density. One of the twin memory transistors is activated by a control gate shared by the twin transistors as a word line and by a select transistor for X-Y transistor addressing of an array. A memory transistor channel cannot conduct for reading, writing or erasing unless an associated select transistor conducts and such conduction is governed by a separate control gate formed by one of three polysilicon layers. A select transistor is a subsurface p-n junction biased by a poly layer. The subsurface source or drain that is spaced from the select transistor must be located in proximity to the memory devices in order to supply charge to the floating gates. By using twin memory devices on either side of a subsurface source or drain, a single subsurface source or drain can service two memory devices in cooperation with a subsurface electrode of a select transistor, one associated with each memory device.

The triple polysilicon (“poly”) layering process involves a first poly layer, poly one, as a floating gate for both of the twin non-volatile memory transistors. The second, interpoly layer, poly two, is a control electrode, electrically communicating with both the floating gate and the subsurface electrode by a T-shape with the top of the T overlying twin spaced apart poly one regions. The third poly layer, poly three, controls select transistors on either side of the twin non-volatile memory transistors, as mentioned above, and serves as a word line for a memory array.

### BRIEF DESCRIPTION OF THE DRAWINGS

FIG. 1 is an electrical schematic of an exemplary non-volatile memory transistor array in accordance with the present invention.

FIG. 2 is a top view of a mask plan for finished fabricated non-volatile memory transistors in the array shown in FIG. 1.

FIGS. 3-7 show sequential processing steps in sectional profile along line X-X in FIG. 2 for formation of thin oxide tunnel windows in the transistors shown in FIG. 2.

FIGS. 8-21 show sequential processing steps in sectional profile along line X-X in FIG. 2 for fabricating transistors shown in the memory array of FIG. 2 after the formation of thin oxide tunnel windows shown in FIG. 7.

FIG. 22 shows finished fabricated non-volatile memory transistors in sectional profile along lines X-X in FIG. 2.

FIG. 23 shows finished fabricated non-volatile memory transistors in sectional profile along lines Y-Y in FIG. 2.

### DETAILED DESCRIPTION

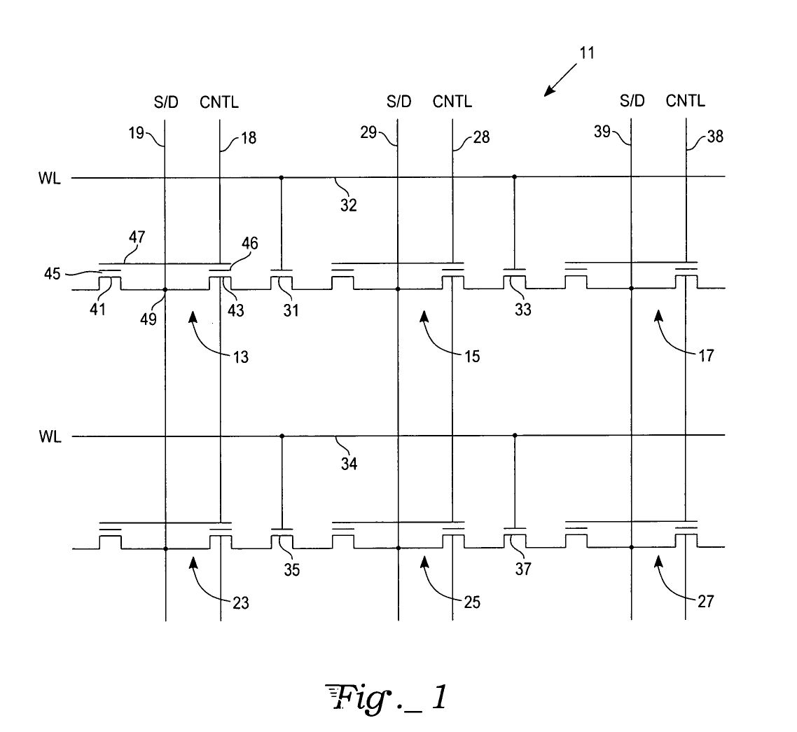

With reference to FIG. 1, non-volatile transistor memory array 11 is seen to be organized with rows and columns of non-volatile memory transistor pairs. For example, in the left hand column of the array, non-volatile memory transistor pairs 13 and 23 exist in the same column. Similarly, non-volatile memory transistor pairs 15 and 25 exist in the middle column and non-volatile memory transistor pairs 17 and 27 exist in the right hand column. Each column has a control line 18, 28, and 38, similar to a bit line, with the control line 18 connected to control gate 47 and to substrate 43 such that the control line 18 extends to the next transistor pair 23. Each of the non-volatile memory transistor pairs has an associated subsurface source-drain electrode line 19, 29, and 39 respectively for the left, middle, and right transistor pair. Each transistor pair has an associated select transistor. For example, the left hand transistor pair 13 has select transistor 31 while the lower left transistor pair 23 has select transistor 35. The middle transistor pair 15 has a select transistor 33 and lower middle transistor pair 25 has select transistor 37, and so on.

The non-volatile memory transistor pairs 13, 15, and 17 are in a top row associated with word line 32. Note that the word line 32 is associated with select transistors 31 and 33 by direct electrical connection. Similarly, the word line 34 is associated with a second row of transistor pairs 23, 25, and 27 in the same manner as word line 32.

The transistor pair 13 features a left side non-volatile memory transistor 41 and a right side non-volatile memory transistor 43. Non-volatile memory transistor 41 has a floating gate 45. Non-volatile memory transistor 43 has a floating gate 46. A single control gate 47 serving both memory transistors 41 and 43 is electrically connected to control line 18. Note that a single control gate 47 connected to control line 18 controls two non-volatile memory transistors through control gate 47, namely transistor 41 and transistor 43. Actually, only one non-volatile memory transistor is controlled at one time when activated by a neighboring select transistor.

Control gate 18 is able to control writing (programming), reading, and erasing of transistors 41 and 43 in cooperation with a corresponding select transistor. Each non-volatile memory transistor pair in memory array 11 has a similar control gate and control gate function. Each non-volatile memory transistor pair has a single subsurface electrode, such as source-drain 49 associated with non-volatile memory transistor pair 13. The subsurface electrode communicates with a corresponding electrode of a select transistor depending on the state of the intervening channel determined by the floating gate of the non-volatile memory transistor overlying the channel. The state of the channel is determined by electrical charge, or absence of charge, on the floating gate. In fabricating the array, no isolation structures are built. The subsurface electrode 49 is sufficiently close to non-volatile memory transistors 41 and 43 to supply charge storage electrons which tunnel through tunnel oxide to floating gates 45 and 46. At the same time, the source-drain subsurface electrode 49 can be sensed, for example, by select transistor 31 through non-volatile memory transistor 43. Each non-volatile memory transistor pair, such as the pair of non-volatile memory transistors 13 comprising the left side transistor 41 and right side transistor 43 forms a pair of separate and distinct memory transistors in a memory array having rows and columns of memory transistors which can be addressed by means of the word lines, as well as the vertical source-drain lines (19, 29, and 39) and simultaneously with the control lines (18, 28, and 38). The benefit of the architecture illustrated in FIG. 1 is that the transistor pairs can be fabricated very closely together, almost as if a single device, yet provide self isolation so that no separate space consuming isolation structures are needed. The area of a non-volatile memory transistor pair with a select transistor is estimated to be nm².

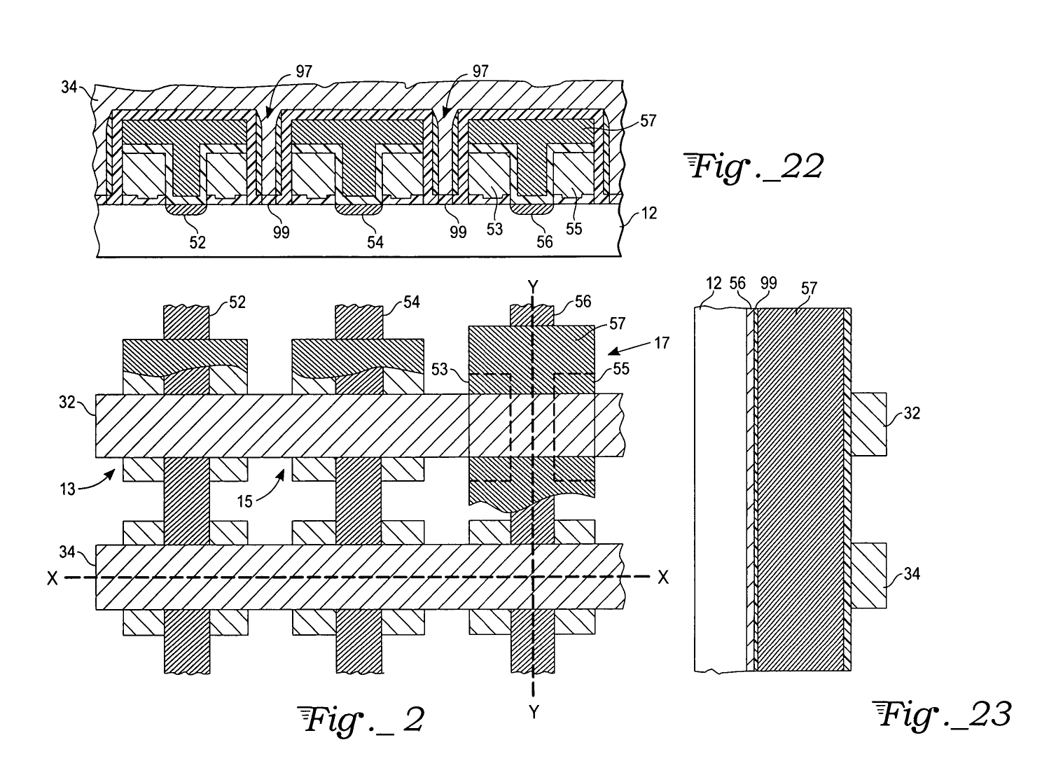

With reference to FIGS. 2, 22, and 23, word lines 32 and 34 are both running horizontally parallel to each other in the array while vertical subsurface electrodes 52, 54, and 56 run in the perpendicular direction. Twin symmetric non-volatile memory transistors 17 have floating gates 53 and 55 indicated by dashed lines, with a line of symmetry being dashed line Y-Y, with control gate 57 overlying the floating gates. Transistor pairs 13 and 15 have similar structures.

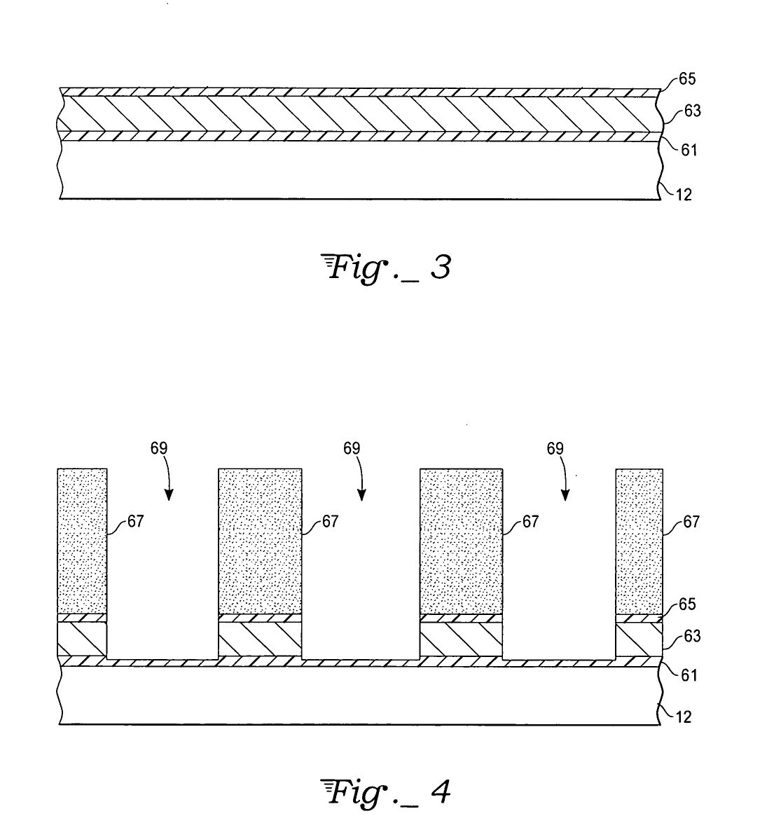

With reference to FIG. 3, a lightly doped semiconductor substrate 12 is provided with a silicon dioxide coating 61 that is typically about 250 angstroms thick. This coating is followed by a polysilicon coating 63, approximately 1,500 angstroms thick. In turn, this is followed by a nitride layer 65, approximately 250 angstroms thick. The layers 61, 63, and 65 extend completely across the substrate 12 in the area with the non-volatile memory array of FIG. 1 needs to be manufactured. The layers are planar and uniform to the extent possible. The nitride-poly-oxide layers 65, 63, 61 are covered with a mask and the mask is etched as seen in FIG. 4, to form openings which extend down to oxide layer 61 but do not remove this layer. Portions of nitride layer 65 and poly layer 63 have been. Masked portions 67 which remain after etching, are to be removed, together with nitride layer 65. Note that oxide layer 61 is slightly recessed where the openings 69 exist. The thinning of the oxide reduces oxide thickness to approximately 50 angstroms at each opening. On the other hand, oxide which was protected by mask layer 67 is over 100 angstroms thick. The thin oxide will subsequently be used for tunnel oxide.

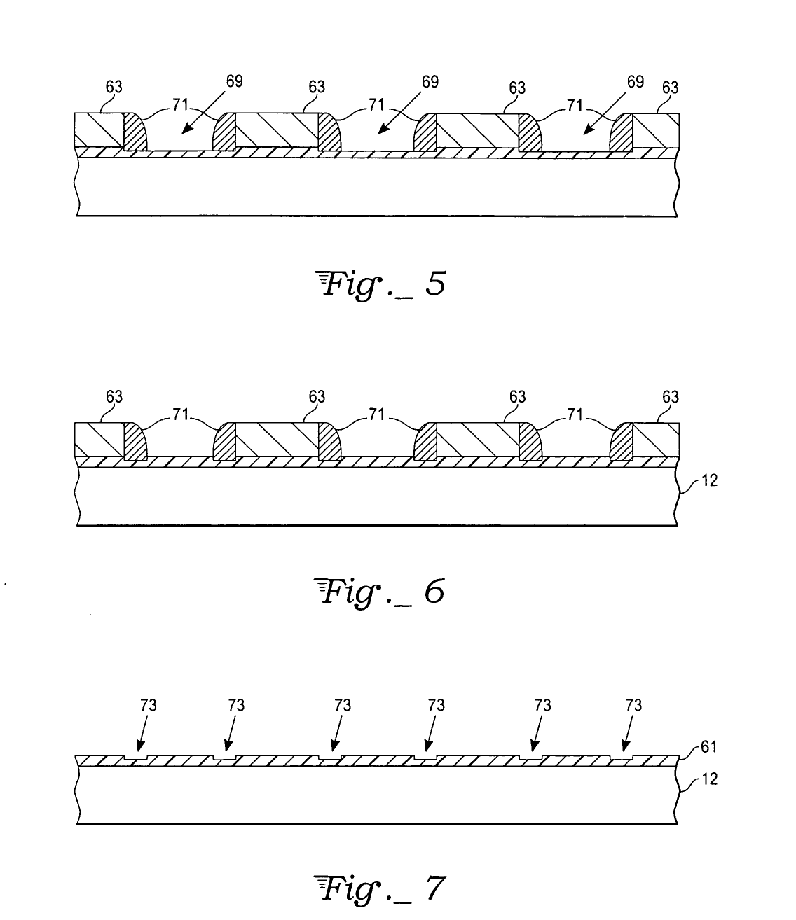

In FIG. 5, spacer segments 71 are portions of a polysilicon layer which was deposited in the openings 69 shown in FIG. 4, with most of the polysilicon then removed, leaving poly spacer segments 71.

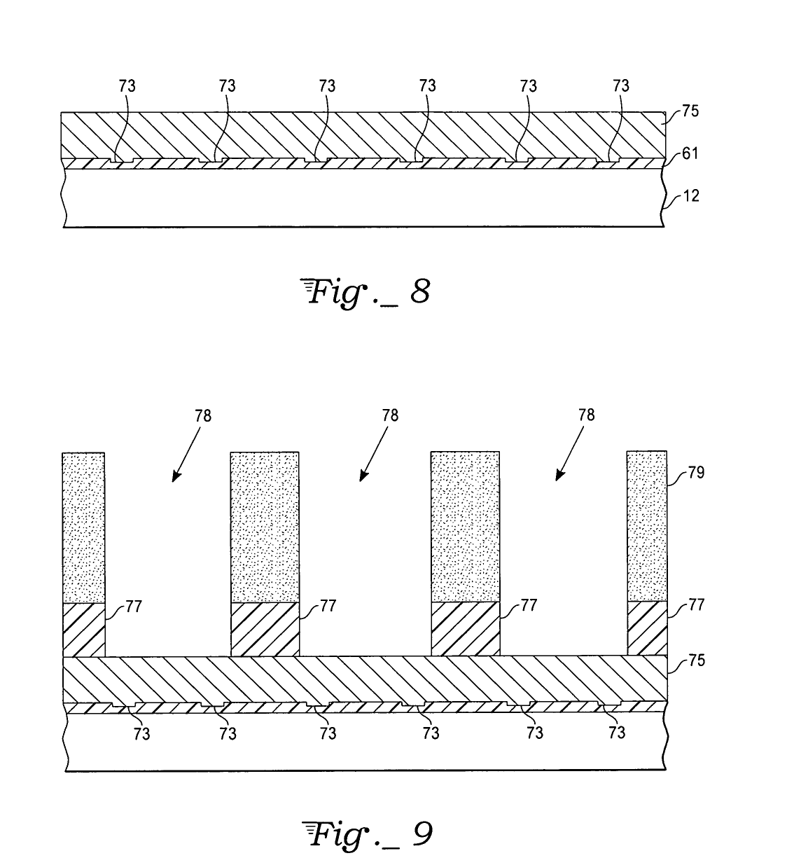

Once these poly spacer segments are in place, the remaining oxide in openings 69 can be brought up to the level of the oxide underneath poly portions 63. This is shown in FIG. 6 where the oxide thickness below poly spacer segments 71 is less thick, approximately 50 Å thick, than oxide beneath poly portions 63, which may be 150 Å thick. After the spacer poly segments 71 and the poly portions 63 are removed, the substrate 12, shown in FIG. 7, is seen to have an oxide layer 61 with thin oxide tunneling windows 73. The width of the spacer segments 71 defined the dimension of the tunnel oxide windows 73. After the formation of the thin windows 73, shown in FIG. 8, a first poly layer 75, termed poly one, is uniformly disposed the oxide layer 61 having the thin tunneling windows 73.

In FIG. 9, the poly one layer 75, covering the thin windows 73, is covered by a nitride layer 77 extending completely across poly one layer followed by a mask layer 79, completely covering the nitride layer 77. The nitride layer is at least as thick as the poly one layer 75. Openings 78 are etched in the mask and nitride layers, leaving nitride islands 77 over poly one layer 75 such that the openings are in alignment with the pair of the tunnel windows 73 plus a slight amount of distance on either side of the window pair.

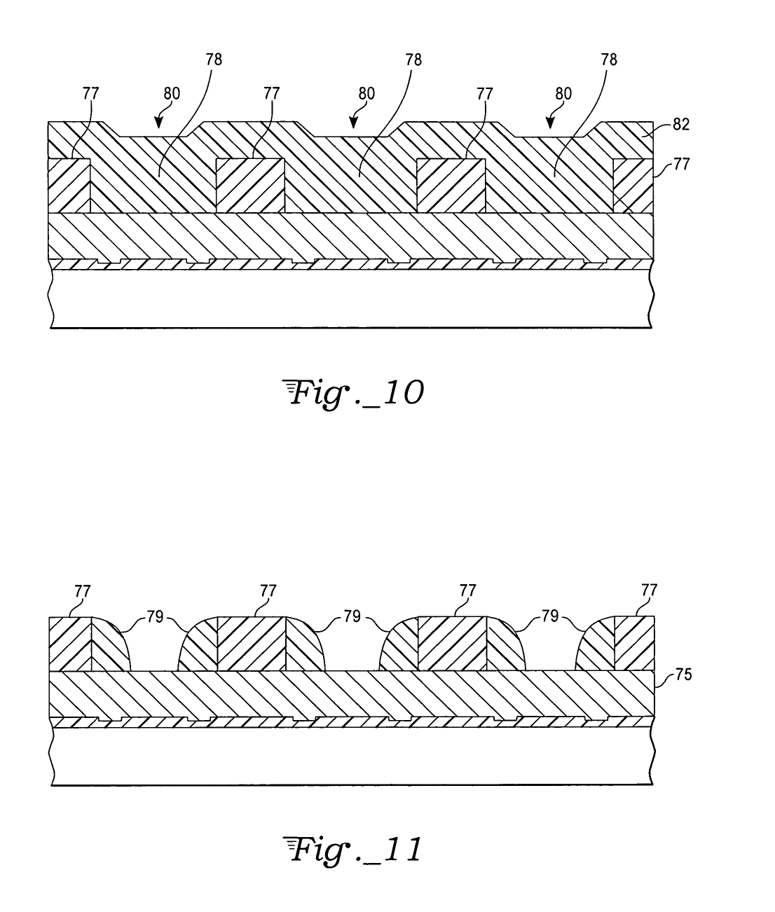

Mask 79 is removed and an oxide layer 82 is used to cover the nitride islands 77, as shown in FIG. 10. Oxide layer 82 fills the openings 78 between the nitride islands 77 as well as covering the nitride islands themselves so that oxide completely covers the structure. Slight indentations 80 exist in the upper surface of the oxide where the oxide has slumped into the space between the nitride islands 77.

Next, the oxide layer 82 is etched to the top of the nitride islands and into the slumping regions 81. All of the oxide is not removed, but rather oxide spacers 79 are left on either side of the nitride islands 77, as shown in FIG. 11. This step provides self-alignment of device features.

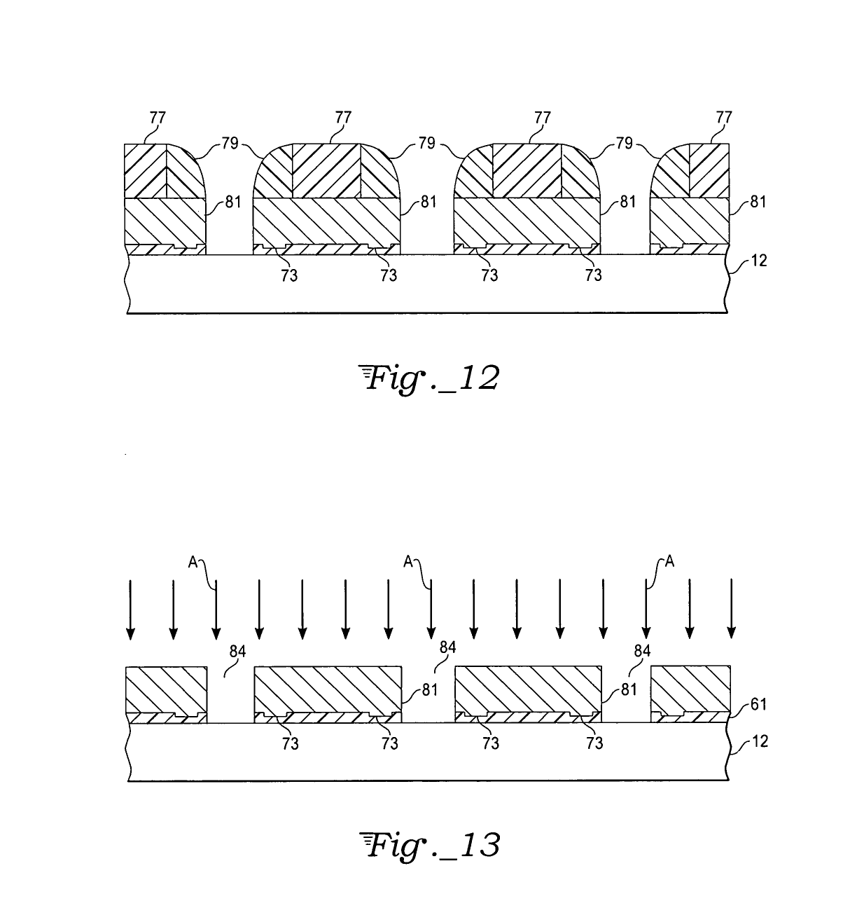

The nitride islands with oxide spacers are etched with a polysilicon etchant forming poly one islands 81 from the polysilicon layer 75, as seen in FIG. 12. The poly one islands 81 each cover a pair of thin oxide windows 73. The nitride islands 77 with the oxide spacers 79 are removed with an etchant so that only the poly one islands 81 remain above the tunnel windows 73 associated with oxide layer 61 above the substrate 12, as seen in FIG. 13. The arrows A indicate ion implantation into the substrate through the openings 84 between the poly one islands 81.

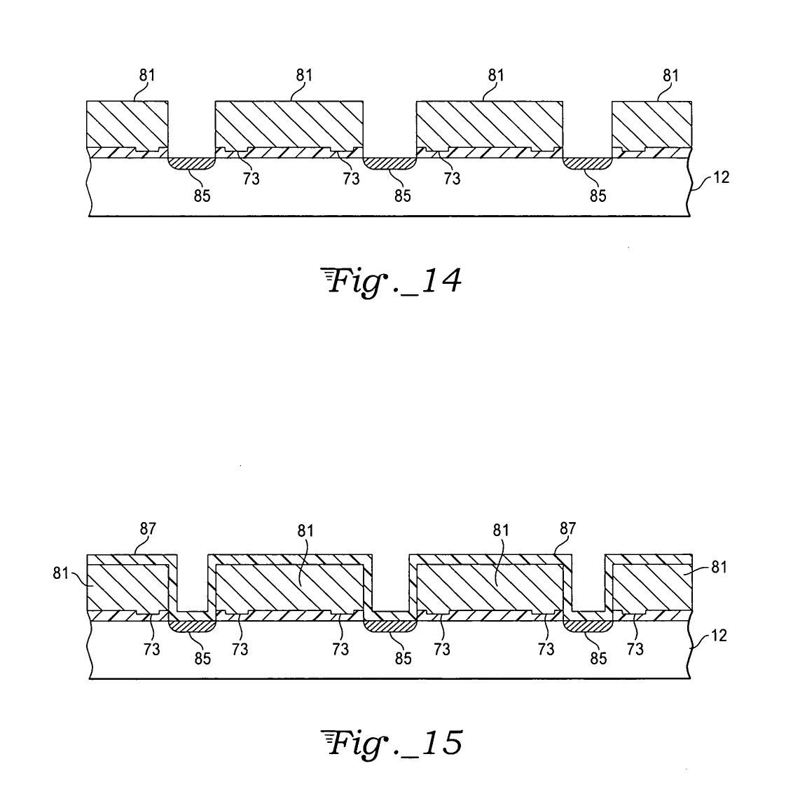

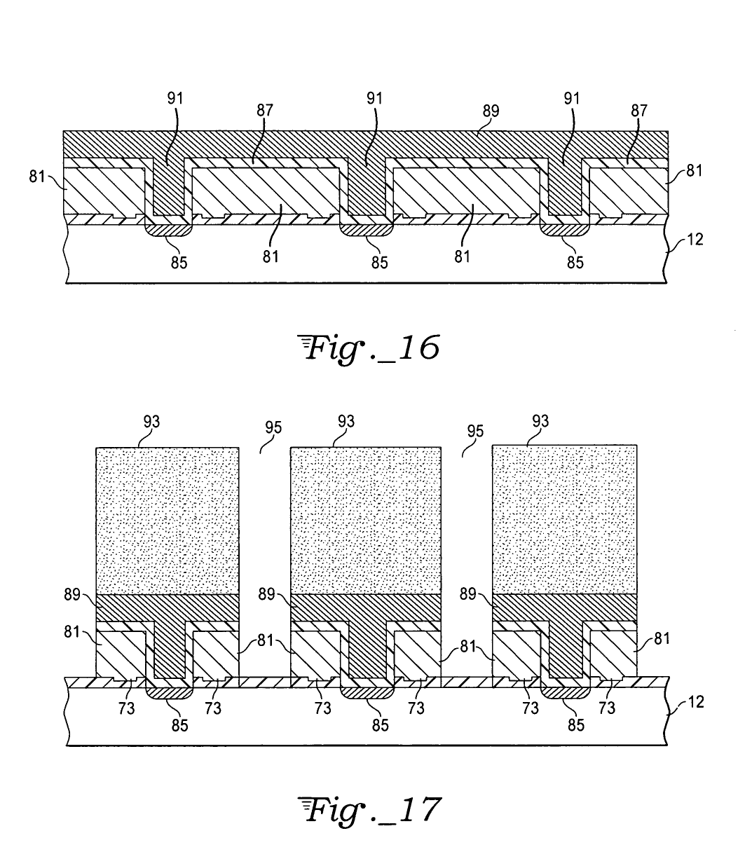

The ion implantation results in subsurface electrodes 85, shown in FIG. 14, between the poly one islands 81 and near the thin tunnel oxide windows 73. Next, a layer of insulative ONO 87 is placed over the structure, including poly one islands 81 as well as over the subsurface electrodes 85, as shown in FIG. 15. In FIG. 16, a poly two layer 89 is deposited over the ONO layer 87 and into the openings 91 between the poly one islands 81. The upper surface of the poly two layer 89 is polished flat and a mask layer 93 is disposed over the poly two layer 89 which is etched to create openings 95, seen in FIG. 17, by splitting the poly one islands 81 so that the split islands are each associated with one of the thin windows 73. Note that the poly two layer regions 89 are now T-shaped, with twin poly one islands under the arms of the poly two T-shape.

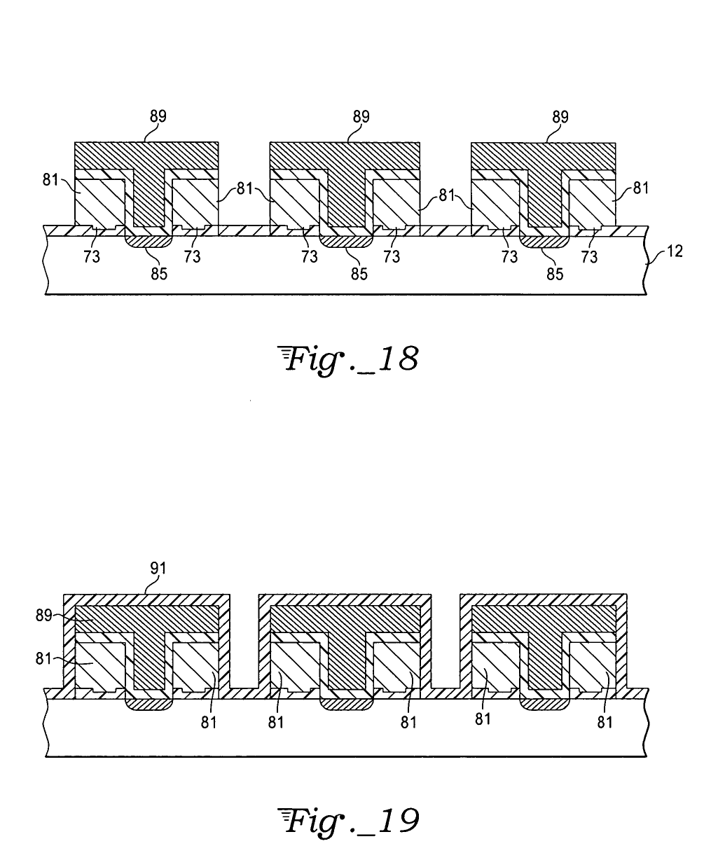

In FIG. 18, the mask layer is removed and each of the split poly one islands 81 may be seen to be over a thin window 73. The poly two T-shapes 89 will act as a control gate for a floating gate transistor having a subsurface implanted electrode 85 supplying charge to a poly one split island 81 acting as a floating gate, with control signals coming from a poly two T-shape 89.

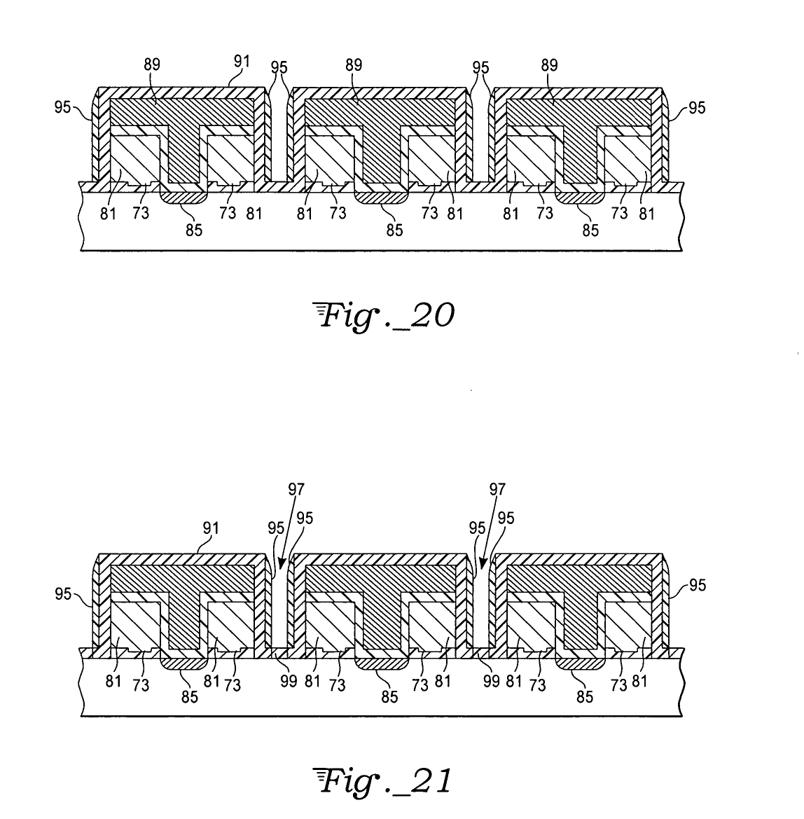

In FIG. 19, an insulative ONO layer 91 is placed over the structure shown in FIG. 18. In FIG. 20, lateral nitride spacers 95 are placed at the sides of the twin poly one islands 81 and associated poly two T-shape, blocking mobile ions from entering the poly one material from a side. From a transistor device standpoint each of the poly one islands will act as a floating gate for charge injected by a subsurface electrode 85 through a thin window 73. Potential for this operation would be supplied on the poly two layer 89. Note that no isolation structures have been fabricated in building pairs of poly one islands 81 for charge storage.

With reference to FIG. 21, ONO layer 91 is etched in the gaps 97 between successive pairs of poly one islands 81 and back filled with oxide 99 and later a poly three layer 34, seen in FIG. 22, to form a poly gate relative to the doped substrate thereby forming a select p-n junction in that location when forward bias is applied. One select junction is associated with a pair of non-volatile memory transistors between the pair of nitride spacers 95 in FIG. 21. While this p-n junction is a diode, a transistor could be built here and the resulting device, whether diode or transistor is called the “select transistor”, a standard term of memory devices.

Transistor formation is finished with annealing of the third poly silicon layer 34. This layer penetrates gaps 97 to contact with gate oxide 99. The third poly silicon layer 34 functions as a word line in reference to the memory cells, as described in FIG. 1.

Typical voltages to be applied to the array of FIG. 1 are as follows:

| | READ | PROGRAM | ERASE |
|---|---|---|---|
| SELECTED WL | +1.8 ÷ +2.5V | +2V | +2V |
| UNSELECTED WL | GND | GND | GND |
| SELECTED COLUMN | +1.8 ÷ +2.5V | +5V | FLOATING |
| S/D (RIGHT OR | | | |
| LEFT) | | | |
| UNSELECTED COLUMN | GND | GND | GND |
| S/D | | | |
| SUBSTRATE (WELL) | GND | GND | GND |
| SELECTED CNTL | +1.5 ÷ 2.5V | +8 ÷ +10V | −8 ÷ −10V |
| UNSELECTED CNTL | GND | GND | GND |

Only one non-volatile memory transistor is addressed by a word line (X) and S/D and CNTL lines (Y) at one time for self-isolation.

1. A semiconductor integrated non-volatile memory structure comprising:
rows and columns of pair of mirror image, non-volatile memory transistors on a single semiconductor, each pair having a single shared control gate.

2. The apparatus of claim 1 wherein pais of mirror image, non-volatile memory transistors in a single row are separated by a select transistor.

3. The apparatus of claim 2 wherein all select transistors in the same row are connected to a common line.

4. The apparatus of claim 3 wherein each non-volatile memory transistor has a floating gate formed in a first polysilicon layer, a shared control gate formed in a second polysilicon layer and an overlying third polysilicon layer contacting the select transistor.

5. The apparatus of claim 4 wherein a subsurface electrode in said substrate is between said mirror image, non-volatile memory transistors.

6. A semiconductor integrated non-volatile memory structure comprising:
twin mirror image floating gate non-volatile memory transistors having first and second polysilicon layers over a semiconductor substrate with a T-shaped second polysilicon layer separating twin floating gates formed in a first polysilicon layer and separated from the second polysilicon layer by an insulative layer, the second polysilicon layer acting as a common single control gate for the twin floating gates.

7. The apparatus for claim 6 wherein said twin mirror image floating gate non-volatile memory transistors are replicated in an array, the array having a third polysilicon layer functioning as word lines.

8. The apparatus of claim 7 wherein adjacent replicated twin mirror image floating gate non-volatile memory transistors are separated by a select transistor in a separation zone contiguous with adjacent twin memory transistors.

9. The apparatus of claim 8 wherein each select transistor was first and second electrode inn said semiconductor substrate, a third electrode formed by the third polysilicon electrode and spaced between the first and second electrodes.

10. The apparatus of claim 6 wherein said twin floating gates are separates from the substrate by twin oxide segments, each oxide segment having a thin tunnel window.

11. The apparatus of claim 7 wherein said array is a monolithic integrated circuit chip without isolation structures between twin mirror image floating gate non-volatile memory transistors.

12. The apparatus of claim 7 wherein pairs of adjacent twin mirror image floating gate non-volatile memory transistors are separated by a select transistor.

13. The apparatus of claim 12 wherein said select transistor has a gate formed by a third polysilicon layer common to all select transistors in a word line of the array.

14. The apparatus of claim 13 wherein the third polysilicon layer overlies the first and second polysilicon layers.

15. The apparatus of claim 13 where source and drain for the select transistor are associated with substrate regions below floating gates of transistors associated with different pairs of twin mirror image floating gate non-volatile memory transistors whereby the second polysilicon.

16. Method of storing charge in a non-volatile memory transistor comprising:
fabricating twin closely spaced non-volatile memory transistors, each transistor having a separate floating gate;
providing a single common electrode for charge supply to the separate floating gates of the twin transistors.

17. The method of claim 16 further defined by providing a single common control gate electrode for the twin transistors.

18. The method of claim 16 further defined by making an array of twin closely spaced non-volatile memory transistors.

19. The method of claim 18 further defined by fabricating said array on a common substrate without isolation structures.

20. The method of claim 18 further defined by providing a select transistors between adjacent pairs of twin non-volatile memory devices.
